(19) United States
(12) Patent Application Publication
(10) Pub. No.: US 2025/0357342 A1
(43) Pub. Date: Nov. 20, 2025

(54) SUBTRACTIVE POWER LINES WITH WRAP-AROUND POWER PLANE

(71) Applicant: INTERNATIONAL BUSINESS MACHINES CORPORATION, Armonk, NY (US)

(72) Inventors: Nicholas Anthony Lanzillo, Wynantskill, NY (US); Albert Manhee Chu, Nashua, NH (US); David Wolpert, Poughkeepsie, NY (US); Ruilong Xie, Niskayuna, NY (US); Lawrence Alfred Clevenger, Saratoga Springs, NY (US); Brent Alan Anderson, Jericho, VT (US)

(21) Appl. No.: 18/664,959

(22) Filed: May 15, 2024

(51) Int. Cl. H01L 23/528; H01L 23/522

(52) U.S. Cl. CPC H01L 23/5286; H01L 23/5226

(57) ABSTRACT

A semiconductor device includes metal lines disposed in a metal level. A dielectric barrier conforms to a top and sides of the metal lines. A power plane is disposed over the dielectric barrier and in-between the metal lines.

### BACKGROUND

The present invention generally relates to semiconductor devices and processing methods, and more particularly to a metal structures for semiconductor devices.

Semiconductor devices include metal structures that can have a number of parallel metal lines connected to metal lines in other layers using vias. In some instances, it is beneficial to have a power distribution network on a backside of a device that can deliver power to components, such as transistors.

### SUMMARY

In accordance with an embodiment of the present invention, a semiconductor device includes metal lines disposed in a metal level. A dielectric barrier conforms to a top and sides of the metal lines. A power plane is disposed over the dielectric barrier and in-between the metal lines.

In accordance with another embodiment of the present invention, a semiconductor device includes a device region including front end of the line (FEOL devices). The device region defines a frontside and a backside opposite the frontside of the semiconductor device. Metal lines are disposed in a metal level on the backside. A dielectric barrier conforms to a top and sides of the metal lines. A power plane is disposed over the dielectric barrier. The power plane extends to a region in between the metal lines to surround the metal lines on three sides of the metal lines.

In accordance with another embodiment of the present invention, a semiconductor device includes a device region including front end of the line (FEOL devices). The device region defines a frontside and a backside opposite the frontside of the semiconductor device. Positively tapered metal lines are disposed in a metal level on the backside. A dielectric barrier conforms to three sides of the positively tapered metal lines. A power plane is disposed over the dielectric barrier on the three sides of the positively tapered metal lines. The power plane extends to a region in-between the positively tapered metal lines. The positively tapered metal lines are associated with a first supply voltage, and the power plane is associated with a second supply voltage different from the first supply voltage.

In other embodiments, the metal lines can include positively tapered shapes over which the dielectric barrier conforms. The power plane can completely or partially encapsulate the dielectric barrier on three sides of the metal lines. The dielectric barrier can include a hard mask portion on tops of the metal lines. The power plane can include vias disposed between the metal lines and connected to a device region. A via connecting to one of the metal lines can pass through the power plane. The metal lines and the power plane can be included in a power distribution network. The power distribution network can be included on a backside of the semiconductor device.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of a semiconductor wafer or device having a metal layer deposited on a device region, in accordance with an embodiment of the present invention;

FIG. 2 shows a cross-sectional view of the semiconductor wafer or device depicting positively tapered metal lines after subtractive etching the metal layer, in accordance with an embodiment of the present invention;

FIG. 3 shows a cross-sectional view of the semiconductor wafer or device depicting a dielectric layer formed over the positively tapered metal lines, in accordance with an embodiment of the present invention;

FIG. 4 shows a cross-sectional view of the semiconductor wafer or device depicting the dielectric layer etched to provide a dielectric barrier on the positively tapered metal lines, in accordance with an embodiment of the present invention;

FIG. 5 shows a cross-sectional view of the semiconductor wafer or device depicting a power plane formed on the dielectric barrier and conforming to the positively tapered metal lines, in accordance with an embodiment of the present invention;

FIG. 6 shows a cross-sectional view of a semiconductor wafer or device having a metal layer deposited on a device region, in accordance with an embodiment of the present invention;

FIG. 7 shows a cross-sectional view of the semiconductor wafer or device depicting positively tapered metal lines having a hard mask remnant formed thereon after subtractive etching the metal layer, in accordance with an embodiment of the present invention;

FIG. 8 shows a cross-sectional view of the semiconductor wafer or device depicting sidewall spacers formed over sides of the positively tapered metal lines, in accordance with an embodiment of the present invention;

FIG. 9 shows a cross-sectional view of the semiconductor wafer or device depicting a power plane formed on the dielectric barrier and conforming to the positively tapered metal lines, in accordance with an embodiment of the present invention;

FIG. 10 shows a cross-sectional view of the semiconductor wafer or device depicting a via to a higher metal level connecting to a positively tapered metal line, the via formed through the power plane, in accordance with an embodiment of the present invention;

FIG. 11 shows a cross-sectional view of the semiconductor wafer or device depicting vias formed to a device region connecting to the positively tapered metal line and the power plane, in accordance with an embodiment of the present invention; and

FIG. 12 shows a cross-sectional view of the semiconductor wafer or device depicting the power plane planarized to form individual metal lines between the positively tapered metal lines, in accordance with an embodiment of the present invention.

### DETAILED DESCRIPTION

In accordance with embodiments of the present invention, devices and methods are described which include a power network and, in particular, a backside power network that includes power lines nested within a power plane. Said differently, the power plane wraps around or partially warps around the wires (with a dielectric barrier between the power plane and the wires). The power network can provide reduced fabrication complexity by reducing a number of fabrication steps while providing a scaling of power line structures to accommodate shrinking pitch sizes in semiconductor devices. Locating the power network on a backside of a devices, leaves available space on a frontside of the chip for signal lines and other metal structures. The power network can provide opportunities to scale a device or chip since power lines can employ a height instead of area for power lines and thereby consume less area on the chip.

In an embodiment, a set of wires is embedded in a blanket deposition of metal. The blanket deposition forms a power plane. A dielectric barrier is formed between the set of wires and the power plane. The power plane wraps around the set of wires, and can encapsulate the wires on up to three sides. The power plane can also form vias that connect to the power plane (in between the wires) to a device region. In some embodiments, vias can be formed concurrently with the blanket deposition of metal to connect to the device region. For example, the power plane can extend from between the wires to form direct backside contacts to the device region. The direct backside contacts can include a scaled height (e.g., taller) to permit a narrower width. This can help reduce their width to support shrinking chip area.

While some embodiments can be integrated on a backside of a wafer, embodiments of the present invention are not limited to placement on the backside of the wafer. In some embodiments, the power network can be integrated on the backside of the wafer, on a frontside of the wafer or both. The power network enables tight spacing between power nets (e.g., positive supply voltage (VDD) and negative supply voltage (VSS)). In an embodiment, the wires can carry positive supply voltage, and the power plane can carry negative supply voltage. In other embodiments, the wires can carry negative supply voltage, and the power plane can carry positive supply voltage.

In accordance with the present embodiments, a power architecture can be formed with just two metal levels, one for the wires and one for the power plane. It should be understood that multiple metal levels can be employed on a same wafer or device.

In accordance with embodiments of the present invention, methods for forming a semiconductor device can include depositing a metal layer. Subtractively etching the metal layer to form metal lines. Depositing a dielectric barrier over the subtractively etched metal lines. The dielectric layer is etched back to remove the dielectric barrier from in between the metal lines. A power plane can be formed over the dielectric barrier by a blanket deposition.

In accordance with another embodiment, methods for forming a semiconductor device can include depositing a metal layer, subtractively etching the metal layer to form metal lines and retaining a hard mask employed by the subtractive etch. A dielectric layer is deposited over the hard mask and the subtractively etched metal lines using a sidewall spacer process. The dielectric layer is etched back to remove the dielectric layer from horizontal surfaces. A power plane can be formed over the dielectric layer by a blanket deposition. Subtractive etching forms positively tapered metal lines or wires. The power plane is deposited (over a dielectric barrier) to fill in spaces between the positively tapered metal lines. This results in negatively tapered portions of the power plane that are disposed between the positively tapered metal lines.

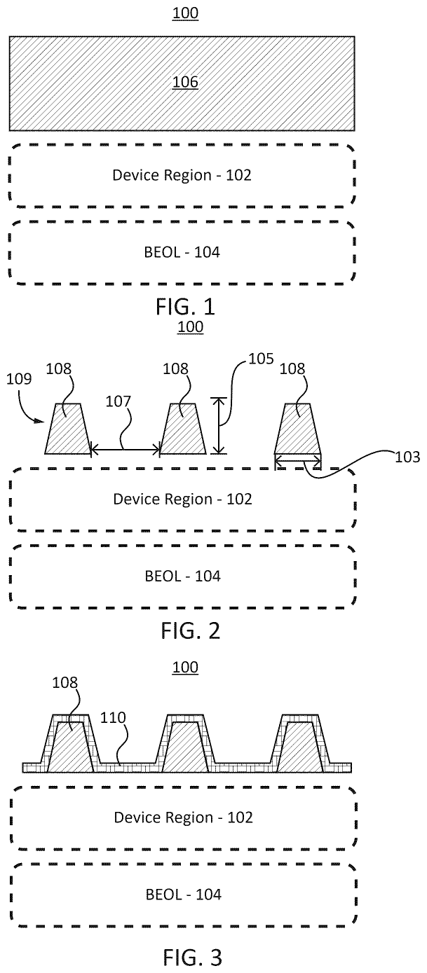

Referring now to the drawings in which like-numerals represent the same or similar elements and initially to FIG. 1, devices and methods for manufacturing a semiconductor device are shown in accordance with embodiments of the present invention. A wafer 100 includes a device region 102 having one or more layers on which semiconductor components are formed. The device region 102 can include front end of the line (FEOL) devices and structures and can include middle end of the line (MOL) devices structures as well. In an embodiment, the device region 102 can include FEOL field effect transistors with source/drain regions, gate structures and other devices. In addition, the device region 102 can include MOL contacts to connect the FEOL structures to a frontside back end of the line (BEOL) region 104. The frontside BEOL region 104 can include metal structures formed within dielectric materials.

A conductive deposition is performed over the device region 102 to form a metal layer 106. The metal layer 106 can include, e.g., Cu, Ru, Mo, Rh, W, Ir, and alloys or combinations of these and other conductive materials. In a particularly useful embodiment, the conductive deposition includes Ru. The conductive deposition can be formed using a deposition method, such as, e.g., chemical vapor deposition (CVD), plasma enhanced CVD (PECVD), atomic layer deposition (ALD) or any other suitable deposition method. The conductive deposition can optionally be planarized, e.g., by chemical mechanical polishing (CMP).

Referring to FIG. 2, a subtractive etch process or processes are carried out to form metal lines 108 (wires) from the metal layer 106. In an embodiment, metal lines 108 are formed by an etch process by exposing portions of the metal layer 106 through an etch mask (not shown). It should be understood that a shape of the metal lines 108 includes a positive taper. The positive taper can be scaled to have an increased height 105, which can be employed to diminish its width 103 while maintaining a desired cross-section for the material of the metal lines 108. In addition, a spacing 107 (or pitch) can be adjusted to conserve area on the wafer 100 and permit space to permit access to higher levels of metal lines.

The metal lines 108 occupy a metal level, which can be referred to as a first metal level 109. It should be understood metal level 109 can be anywhere in a stack of metal levels and is not limited to being positioned in a first metal level position.

It should also be understood that different sizes of metal lines 108 can be provided. In some embodiments, one, two, three or more metal lines 108 of differing height and/or widths can be fabricated, as needed in accordance with a particular embodiment.

Referring to FIG. 3, a dielectric layer 110 is formed on the wafer 100. The dielectric layer 110 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 110 can be conformally deposited using CVD or ALD, although other deposition methods can be employed.

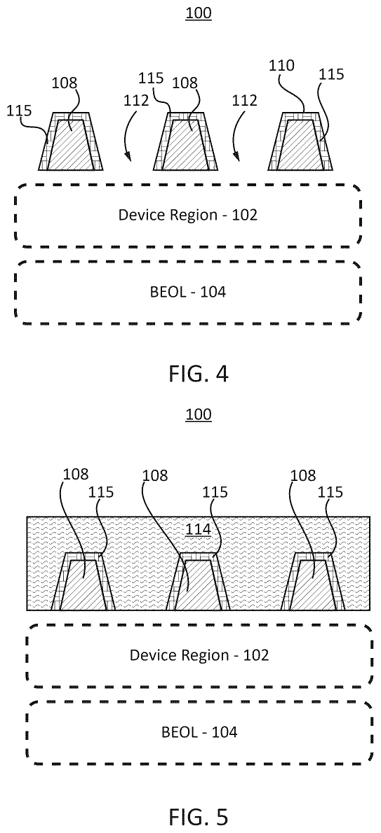

Referring to FIG. 4, the dielectric layer 110 is etched back to remove the dielectric layer 110 from horizontal surfaces 112 in between the metal lines 108. The etch back process can include a reactive ion etch or other plasma etch that removes the dielectric layer 110 from horizontal surfaces while maintaining a dielectric barrier 115 over tops and sides of the metal lines 108.

Referring to FIG. 5, a blanket deposition is performed over the dielectric barrier 115. The blanket deposition can include, e.g., Cu, Ru, Mo, Rh, W, Ir, and alloys or combinations of these and other conductive materials. In a particularly useful embodiment, a conductive material of the blanket deposition includes Cu. The conductive material can be formed using a deposition method, such as, e.g., CVD, plasma enhanced CVD (PECVD), ALD or any other suitable deposition method. The conductive material can be planarized, e.g., by CMP. In an embodiment, the CMP can expose a top surface of the dielectric barrier 115 making the blanket deposition between the metal lines 108 form a second set of independent metal lines (see FIG. 12). In other embodiments, the blanket deposition forms a power plane 114. The power plane 114 and the metal lines 108 can form a power network that can be integrated on a backside of the wafer 100 (or on a frontside of the wafer 100 or both). The power network enables tight spacing between metal lines 108 and spacings 107 between the metal lines 108. Power nets can be provided using the two metals, e.g., the metal lines 108 and the power plane 114. In an embodiment, the metal lines 108 can carry positive supply voltage, and the power plane 114 can carry negative supply voltage. In other embodiments, the metal lines 108 can carry negative supply voltage, and the power plane 114 can carry positive supply voltage.

The two metals, e.g., the metal lines 108 and the power plane 114 can include a same material or different materials. Processing can continue with the formation of additional components, which can include additional dielectric layers and metal structures.

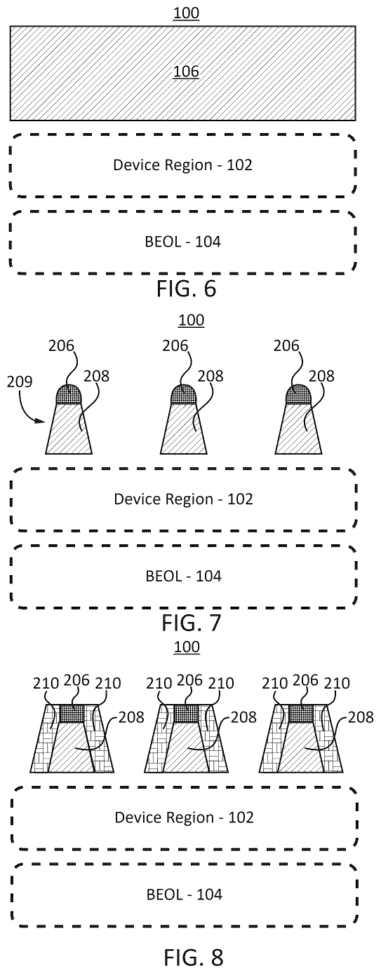

Referring to FIG. 6, in another embodiment, a conductive deposition is performed over the device region 102 to form the metal layer 106. The metal layer 106 can include, e.g., Cu, Ru, Mo, Rh, W, Ir, and alloys or combinations of these and other conductive materials. In a particularly useful embodiment, the conductive deposition includes Ru. The conductive deposition can be formed using a deposition method, such as, e.g., chemical vapor deposition (CVD), plasma enhanced CVD (PECVD), atomic layer deposition (ALD) or any other suitable deposition method. The conductive deposition can optionally be planarized, e.g., by chemical mechanical polishing (CMP).

Referring to FIG. 7, a subtractive etch process or processes are carried out to form metal lines 208 (wires) from the metal layer 106. In an embodiment, metal lines 208 are formed by an etch process by exposing portions of the metal layer 106 through an etch mask 206. The etch mask can include a hard mask patterned using a photolithographic process. The hard mask employed for the etch mask 206 need to include a dielectric material having properties that are satisfactory to act as a dielectric barrier.

It should be understood that a shape of the metal lines 108 includes a positive taper. The positive taper can be scaled to have an increased height and a diminished width while maintaining a desired cross-section for the material of the metal lines 208. In addition, a spacing (or pitch) can be adjusted to conserve area on the wafer 100 and permit space to permit access to higher levels of metal lines. The positive taper includes a narrower width outward from the device or wafer 100 such that the metal lines 108 include a wider base in contact with the device or wafer 100.

The metal lines 208 occupy a metal level, which can be referred to as a first metal level 209. It should be understood metal level 209 can be anywhere in a stack of metal levels and is not limited to being positioned in a first metal level position. It should also be understood that different sizes of metal lines 208 can be provided. In some embodiments, one, two, three or more metal lines 208 of differing height and/or widths can be fabricated, as needed in accordance with a particular embodiment.

Referring to FIG. 8, a dielectric layer 210 is formed on the wafer 100 in a sidewall spacer process. The dielectric layer 210 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 210 can be conformally deposited using CVD or ALD, although other deposition methods can be employed.

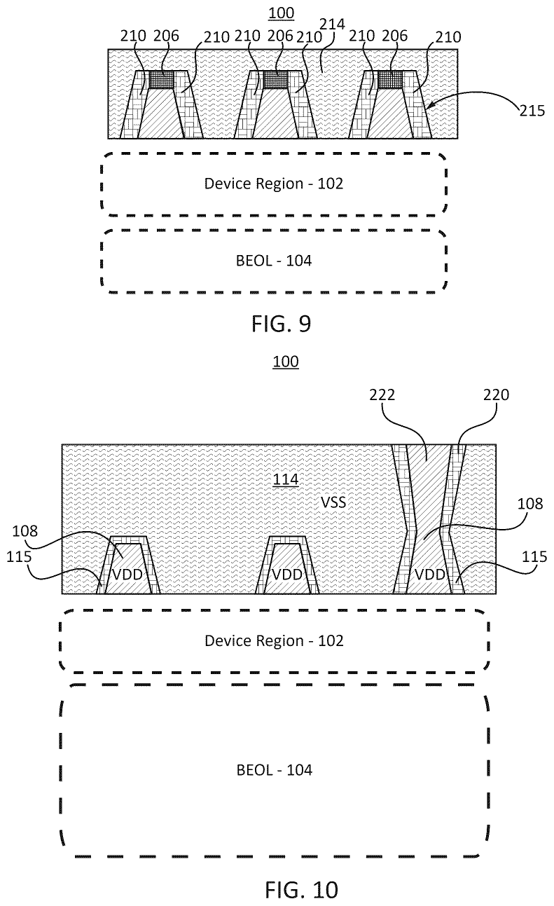

Referring to FIG. 9, the dielectric layer 210 is etched back to remove the dielectric layer 210 from horizontal surfaces 112 in between the metal lines 208 in a spacer etch process. The spacer etch can include a reactive ion etch or other plasma etch that removes the dielectric layer 210 from horizontal surfaces while maintaining a dielectric barrier 215 on sidewalls sides of the metal lines 208. A top portion of the dielectric barrier 215 includes the hard mask employed as the etch mask 206. The etch mask 206 can include a suitable material that is compatible with the material employed for the dielectric layer 210 to form sidewall spacers.

Referring to FIG. 10, in an embodiment, a via 222 can be formed to contact a metal line 108. The power plane 114 can be patterned to open a hole for the via 222 over the metal line 108 to which the via 222 will connect. A dielectric layer 220 is formed in the opening (and on a surface of the power plane 114). A deposition process is performed to deposit conductive material for the via 222. The conductive material can include, e.g., Cu, Ru, Mo, Rh, W, Ir, and alloys or combinations of these and other conductive materials. The conductive material can be formed using a deposition method, such as, e.g., CVD, PECVD, ALD or any other suitable deposition method. The conductive material and the dielectric layer 220 are can be planarized, e.g., by CMP, to form the via 222.

Positive supply voltage VDD is carried by the metal lines 108 and negative supply voltage VSS is carried by the power plane 114. In other embodiments, negative supply voltage VSS can be carried by the metal lines 108 and positive supply voltage VDD can be carried by the power plane 114. The metal lines 108 and the power plane 114 can include a same material or different materials.

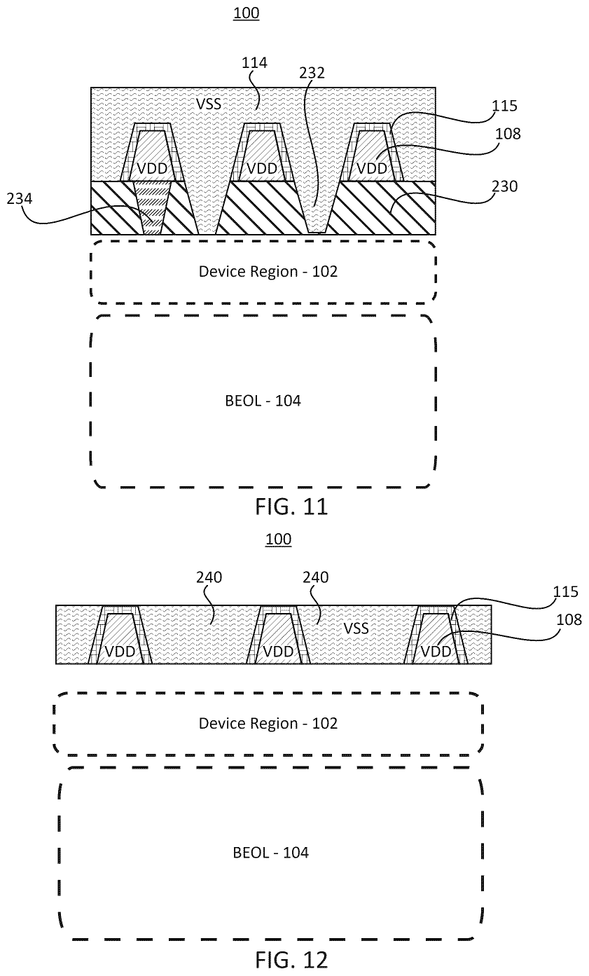

Referring to FIG. 11, in an embodiment, vias 234 can be formed to contact a metal line 108. After a dielectric layer 230 is formed, the dielectric layer 230 can be patterned and via holes can be opened up to be filled with a conductive material. The conductive material is deposited to fill the via holes. Then, the conductive material is planarized (e.g., by CMP), and the vias 234 are formed. The metal lines 108 are formed in contact with the vias 234 during the deposition of the metal layer 106 (FIG. 1, FIG. 6). After formation of the metal lines 108 and the dielectric barrier 115, an etch mask can be formed over the dielectric barrier 115 and openings can be etched (self-aligned) into the dielectric layer 230. During the blanket deposition to form the power plane 114, vias 232 can be concurrently formed from the same conductive material in a damascene process.

In an alternative embodiment, the vias 232 can be formed with vias 234 prior to the formation of the metal lines 108. In this embodiment, formation of the power plane would contact the previously formed vias 232.

Positive supply voltage VDD is carried by the metal lines 108 and negative supply voltage VSS is carried by the power plane 114. In other embodiments, negative supply voltage VSS can be carried by the metal lines 108 and positive supply voltage VDD can be carried by the power plane 114. The metal lines 108 and the power plane 114 can include a same material or different materials.

Referring to FIG. 12, in another embodiment, a planarization (e.g., CMP) process can be performed after the blanket deposition employed for the formation of the power plane 114. In this way, a second set of metal lines 240 can be formed, interspaced and nested between the metal lines 108. The metal lines 108 and the metal lines 240 are separated by the dielectric barrier 115.

Positive supply voltage VDD is carried by the metal lines 108 and negative supply voltage VSS is carried by the metal lines 240. In other embodiments, negative supply voltage VSS can be carried by the metal lines 108 and positive supply voltage VDD can be carried by the metal lines 240. The metal lines 108 and the metal lines 240 can include a same material or different materials.

It should be understood that the embodiments described in FIGS. 10-12 can be applied to the structure of FIG. 9 as well as the structure of FIG. 5, as described. In addition, openings or breaks can be formed through the power plane of the embodiments described in accordance with the present invention. These openings can be employed to permit skip vias, or other conductive connections through the power plane without contacting the power plane. In other embodiments, the power planes described can be employed for shielding purposes. For example, the power plane can function as a ground plane.

Further, the power plane can completely cover sidewalls of the dielectric barrier over the metal lines, or in some embodiments, the power plane can partially cover a height of the metal lines. In this way, the power plane does not extend all the way down to the base of the metal line.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise, ft will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
metal lines disposed in a metal level;
a dielectric barrier conforming to a top and sides of the metal lines; and
a power plane disposed over the dielectric barrier and in-between the metal lines.

2. The semiconductor device as recited in claim 1, wherein the metal lines include positively tapered shapes over which the dielectric barrier conforms.

3. The semiconductor device as recited in claim 1, wherein the power plane encapsulates the dielectric barrier on three sides of the metal lines.

4. The semiconductor device as recited in claim 1, wherein the dielectric barrier includes a hard mask portion on tops of the metal lines.

5. The semiconductor device as recited in claim 1, wherein the power plane includes vias disposed between the metal lines and connected to a device region.

6. The semiconductor device as recited in claim 1, further comprising a via connecting to one of the metal lines that passes through the power plane.

7. The semiconductor device as recited in claim 1, wherein the metal lines and the power plane are included in a power distribution network.

8. The semiconductor device as recited in claim 7, wherein the power distribution network is included on a backside of the semiconductor device.

9. A semiconductor device, comprising:
a device region including front end of the line (FEOL) devices, the device region defining a frontside and a backside opposite the frontside of the semiconductor device;
metal lines disposed in a metal level on the backside;
a dielectric barrier conforming to a top and sides of the metal lines; and
a power plane disposed over the dielectric barrier, the power plane extending to a region in-between the metal lines to surround the metal lines on three sides of the metal lines.

10. The semiconductor device as recited in claim 9, wherein the metal lines include positively tapered shapes over which the dielectric barrier conforms.

11. The semiconductor device as recited in claim 9, wherein the dielectric barrier includes a hard mask portion on tops of the metal lines.

12. The semiconductor device as recited in claim 9, wherein the power plane includes vias disposed between the metal lines and connected to the device region.

13. The semiconductor device as recited in claim 9, further comprising a via connecting to one of the metal lines that passes through the power plane.

14. The semiconductor device as recited in claim 9, wherein the metal lines and the power plane are included in a backside power distribution network.

15. A semiconductor device, comprising:
a device region including front end of the line (FEOL) devices, the device region defining a frontside and a backside opposite the frontside of the semiconductor device;
positively tapered metal lines disposed in a metal level on the backside;
a dielectric barrier conforming to three sides of the positively tapered metal lines; and
a power plane disposed over the dielectric barrier on the three sides of the positively tapered metal lines, the power plane extending to a region in-between the positively tapered metal lines;
wherein the positively tapered metal lines are associated with a first supply voltage and the power plane is associated with a second supply voltage different from the first supply voltage.

16. The semiconductor device as recited in claim 15, wherein the dielectric barrier includes a hard mask portion on tops of the positively tapered metal lines.

17. The semiconductor device as recited in claim 15, wherein the power plane includes vias disposed between the positively tapered metal lines and connected to the device region.

18. The semiconductor device as recited in claim 15, further comprising a via connecting to one of the positively tapered metal lines that passes through the power plane.

19. The semiconductor device as recited in claim 15, wherein the positively tapered metal lines and the power plane are included in a backside power distribution network.

20. The semiconductor device as recited in claim 15, wherein the first supply voltage includes a positive supply voltage.
